(19) United States
(12) Patent Application Publication
(10) Pub. No.: US 2003/0163637 A1
(43) Pub. Date: Aug. 28, 2003

(54) Memory system for searching a longest match

(76) Inventors: Yves Emmanuel Villaret, Hadera (IL); Shmuel Prokopets, Bnei Brak (IL)

Correspondence Address: LOWE HAUPTMAN GILMAN AND BERNER, LLP, 1700 DIAGONAL ROAD, SUITE 300 /310, ALEXANDRIA, VA, 22314, US

(21) Appl. No.: 10/240,414

(22) PCT Filed: Feb. 1, 2001
(86) PCT No.: PCT/IL01/00096

(51) Int. Cl. G06F 12/00; G11C 15/00

(52) U.S. Cl. 711/108; 365/49

(57) ABSTRACT

A method and circuit to be applied in content addressable memories for finding a word with the longest match to the searched data. A word of data is stored in each memory cell, the word of data is composed of a group of sub words in a predefined order and each sub word is composed of one or more bits of memory. All sub words having the same position within the sub word sequence of their respective words are associated with the same tranversal line, and the method comprises the steps of

a) setting a still match signal for a first subword that matches the searched data

b) setting a still match signal for a subword in the event that all the previous match signals, for all subwords of the same word in a pre-defined order have been set, the said still match signal being the AND logic combination of the associated sub-word matching signal and all the preceding, in the said predefined order, still match signals

c) setting the transversal line to logical 1 if a still match is set for any of the subwords to which the said transversal line is associated

d) setting a longest match signal at the last consecutive matching subword of a word if the conditions are satisfied that: i)—the still match signal of that sub-word is set, and ii)—the transversal line at the next sub-word position in the word is not set.

e) Setting a word match signal if any of the longest match signals for any subword of the said word is set.

### FIELD OF THE INVENTION

In communication systems, of which the World Wide Web is one example, a large number of messages (packets) are transmitted. Each message contains a destination address, and must be routed according to that destination by a routing system. The address of the destination may be stored in a word with a fixed length. Groups of addresses having a common prefix are usually assigned to the same domain, and thus require the same routing. However, these Domain addresses may have different lengths. A routing system generally contains tables of a great number of Domain prefixes in memory, and executes a search to check whether the address of an incoming message belongs to a given domain. If the address is found, then the routing information is retrieved from an associated table. Since a routing system may have a large amount of messages to dispatch at high speed, it would be desirable to design a system for finding the longest prefix of the addresses that matches a stored prefix of the table, that system working at high speed.

In PCT WO 00070832A1, background of the invention, the need for an economical and fast Longest Prefix Searching system is well explained.

In existing routing systems, various algorithms accomplish the Longest Prefix Search, using several memory search cycles. In many routing systems, Content Addressable Memories are used to search a prefix with a given length, and several iterative searches are done in software or hardware, using varying size for the search, until the Longest Match is found. Examples of such systems are described in U.S. Pat. No. 6,067,574; U.S. Pat. No. 5,983,223 and U.S. Pat. No. 6,052,683.

It would be desirable to provide means for finding at high electronic speed the position of one memory cell in a content addressable memory array, that memory cell storing a word of data having the maximum number of consecutive matching bits among all the memory cells in that array. It would be further desirable to enable the execution of such a “Longest Match Searching” operation in a single memory cycle.

It would be advantageous to implement the “Longest Match Searching” operation at electronic speed by means of an electronic circuit.

### SUMMARY OF THE INVENTION

It is the purpose of the memory system described herein to provide means to find at electronic speed the position of one memory cell in a content addressable memory array, that memory cell storing a word of data having the maximum number of consecutive matching bits among all the memory cells in that array. The Longest Match Searching operation, being done by electronic circuitry only, can be done in a single memory cycle, using a method wherein:

Each word data comprises a group of Sub Words that are arranged in a predefined order,

The Sub-Word match signal M_{i,j} of a given Sub-Word B_{i,j} is set according to the output of the comparator of that Sub-Word;

Consecutive Matching Sub-Words of a Word Wᵢ, are detected by means of a “Still Match” signal that is separately generated at each Sub-Word;

Each “Match” output of a Sub-Word is combined with the “Still-Match” signal of the previous Sub-Word of the same Word by means of an AND logic gate, the first Sub-Word of the Word being an exception, in which case the “Still Match” signal is just set to the same signal as the “Match” signal;

The Still Match signal is set (logic 1) if all Sub-Words preceding the present Sub Word contain matching data, whereby for each word having at least a first Sub-Word matching, a “Matching Chain” of set signals is achieved;

and the Longest Match is found by finding the longest Matching Chain.

The task of finding the length of the longest Matching Chain(s) is performed in the following way:

For each possible position of a Sub-word, with the exception of the first position, a Transversal line is associated. Each Transversal line is then set to logic level 1 if and only if at least one of the Still-Match signals among all words of the memory array is set to logic level 1. This is done by means of an “OR” combination of all Still Match signals of all words for a given sub-word position.

In this way, each Word “Marks” on the transversal lines its ultimate length of matching chain. Finally the line with logical level 1 at the highest position indicates the length of the longest Matching Chain.

The Sub-Word(s) at the end of the longest matching chain is detected by combining in a logic gate the signal on the transversal line associated with a Sub Word and the signal on the next transversal line such that a “Longest Match” signal is achieved in case that the

Signal on the first transversal line is set but the signal on the next transversal line is not set.

Where the Still Match signal is set for the last Sub-Word of a word, it is obviously in the longest Matching Chain. Therefore for the last Sub-Word the Longest Match signal is set identical to the Still Match Signal.

Finally, a Word Match Signal is activated for each word where a Matching Chain with the longest length has been detected. This is done by collecting all the longest Match signals for a word by a wide OR gate.

As in the case of standard CAM, several words of memory may activate the Word Match signal, each one satisfying the Longest-Match condition. However a CAM or COM may include a priority encoder, or a Priority Mask, in order to select only the Address of one cell for output, the selection being done according to the priority system of the specific type of CAM or COM. Such Priority Mask has been described in detail in PCT/IL 00/00121.

The present invention can be advantageously used in communication systems as well as in other systems such as, for example, in data base and data compression systems.

### BRIEF DESCRIPTION OF THE DRAWINGS

FIG. 1 shows a typical general block diagram of a content addressable memory often used as a component in Longest Match Searching systems.

FIG. 2 shows how the Word Match signal is generated in a typical content addressable memory.

FIG. 3 shows a preferred embodiment of the invention combined in a CAM or COM.

FIG. 4 shows the details of the circuitry associated to one Sub-Word in the preferred embodiment.

FIG. 5 shows how, in the preferred embodiment, all Sub-Words at a given position j, of all Words, activate the Transversal Line Tj

FIG. 6 shows how the Word Match line of a Word Wᵢ is activated if one of its Sub-Word activates the Longest Match output.

FIG. 7 shows a generic example of the implementation of the preferred embodiment in a VLSI circuit.

FIG. 8 shows a VLSI circuit for sub word positions 1, 2, 3.

FIG. 9 shows the details of the circuit of the area of FIG. 8 that is circled by a dashed line.

### DETAILED DESCRIPTION OF A PREFERRED EMBODIMENT

The present invention relates to an electronic circuit and system that can be combined in a Content Addressable Memory (CAM) or a Call Out Memory (COM) in order to find the longest match word in a single search cycle. The principle of the present invention can also be used to design a CAM or COM that registers the size of the Longest Match according to the number of transversal lines that have been set. In such a CAM, after the size of the Longest Match has been found, an exact search can be done using a second CAM or COM of the common type, or using the same CAM or COM working in a common CAM or COM mode, while masking the bits beyond the longest match.

In CAM, COM or other Associative Memories, a comparator is provided in each memory cell, that detects the matching of the content of the memory cells with a reference data presented to the memory device. Whenever the content of one memory cell verifies a given relationship with the reference data (matching cell), the comparator outputs a logic signal. This logic signal then activates a system that outputs the position of one of the matching cells according to the priority system of the specific CAM or COM.

It is the purpose of the memory system according to the invention to provide means to find at electronic speed the position of one memory cell in a content addressable memory array, that memory cell storing a word of data having the maximum number of consecutive matching bits among all the memory cells in that array. In accordance with the inventive system, such a Longest Match Searching operation is done by electronic circuitry only and it can be done in a single memory cycle.

The present invention can be advantageously used in communication systems as well as in other systems such as, for example, in data base and data compression systems.

Depending on the specific applications, bits may be assigned to groups (Sub-Words), and the Longest Match function may be applied to these Sub-Words. In that case, we shall refer to a Longest Match Word as the Word of data having the longest chain of consecutive matching Sub-Words. An example of such an application is where the longest match is to be searched in a table of text strings, where each character of the string occupies an eight bit word.

Since the invention relates to a system to be combined in a CAM, w e shall first give a general description of a typical CAM with reference to the drawings. It will be understood that the drawings are schematic representations of electronic circuits using straight geometric lines and the actual configuration of these circuits may not conform to the drawings.

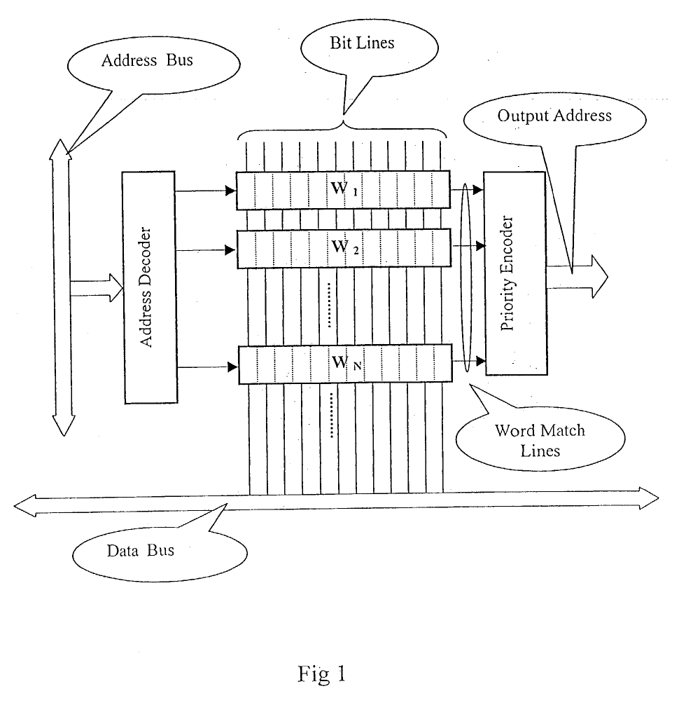

In FIG. 1, a commonly used Content Addressable Memory is shown. A number of memory cells, W₁ to Wₙ, each one being able to store a word of data, are connected to an Address Bus through an Address Decoder, and to a Data Bus by means of a plurality of Bit Lines.

The CAM has two operating modes.

In a first, Read/Write mode, data can be written to or retrieved from memory cells. In a second, CAM mode, data is applied on the Data Bus, and the memory returns the address of a memory cell storing matching data. For that purpose, each memory cell also includes a comparator circuit. That Comparator outputs, when the system is placed in the CAM Mode, a Match Word signal if a predefined relationship is verified between the Data Stored in the Word, and the Data Applied on the Data bus. If one or more than one Word outputs a Word Match signal, then a priority system or circuit is used to select the address of one Word only for output, the selection being done according to the specific rules defined for the CAM.

FIG. 1 shows one type of Content Addressable Memory, however there are many variations for the architecture of such a CAM, to which, as will be shown, the inventive circuitry can be applied. Implementation of the inventive principle is not dependent on the type of memory architecture, and the circuit of this invention can be combined in the various types of CAM or COM.

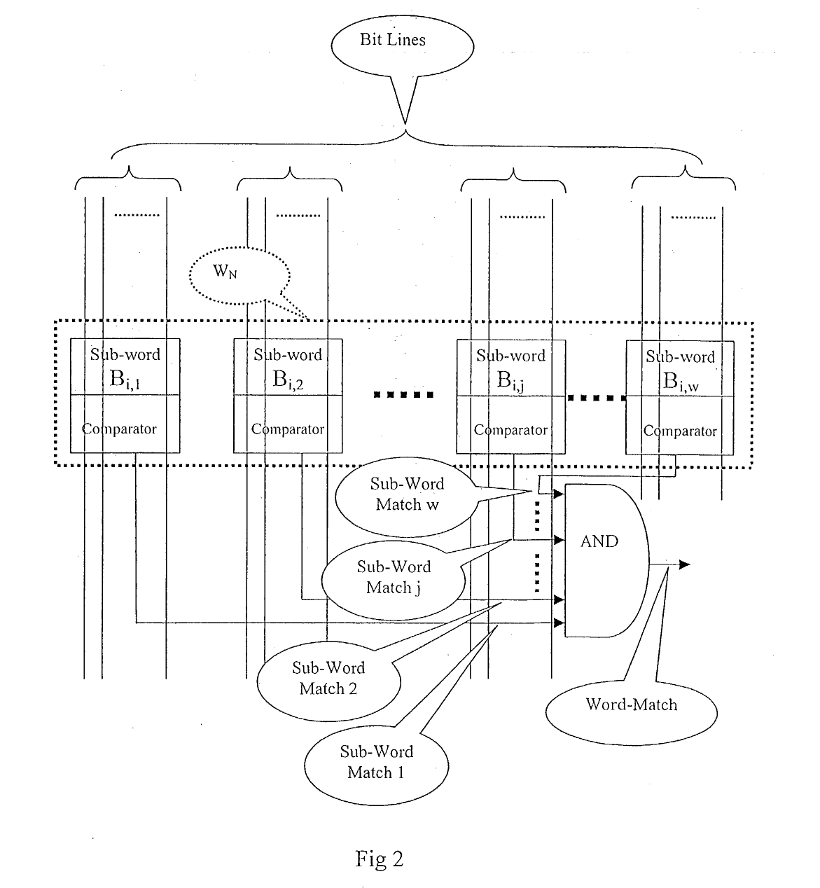

In FIG. 2 the generation of a Match Word signal in a Content Addressable Memory of the prior art is shown. In this example, a memory cell stores a word W_{N} of data, that word being composed in a number w of sub-words {B_{i,1}, . . . B_{i,j}, . . . B_{i,w}}. Typically, each sub-word will be composed of a bit, or a number of bits.

To each sub-word B_{i,j}, a comparator is associated. The comparator compares data stored in the sub-word with data set on the bit lines, and sets a Sub-Word Match signal if a predefined relationship is verified. Typically, the relationship will be just equality, however any kind of relationship can be envisaged.

All Sub-word Match signals of one word are then input to an AND logic gate to form a Word-Match signal. The Word-Match signal will thus be set to a logical level one if all Sub-Words are found matching.

It will be understood that in such a system, all Sub-Words must be matching in order to activate the Word-Match signal.

It is the purpose of the present invention to propose a system that activates the Word-Match signal according to a new condition, even if all sub-words are not matching. This new condition will be to activate the Word-Match signal if the number of consecutive Matching Sub-Words, starting from a first Sub-Word, is the highest among all the words stored in the searched memory. This condition will be referred to as the Longest Match condition.

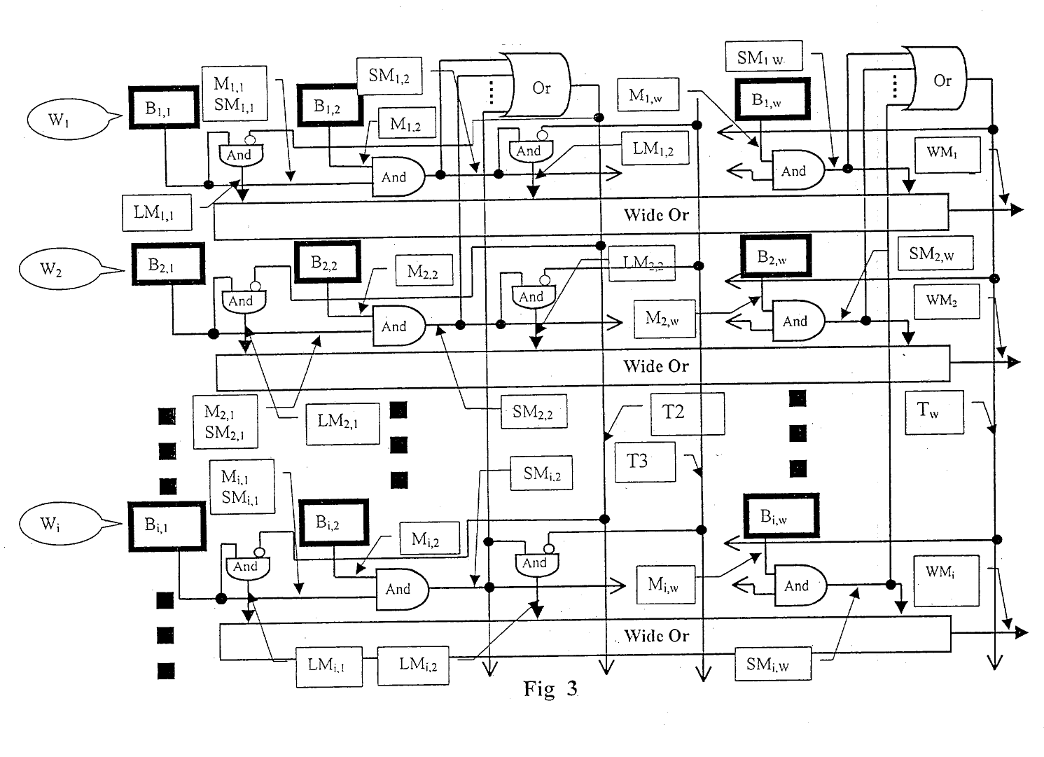

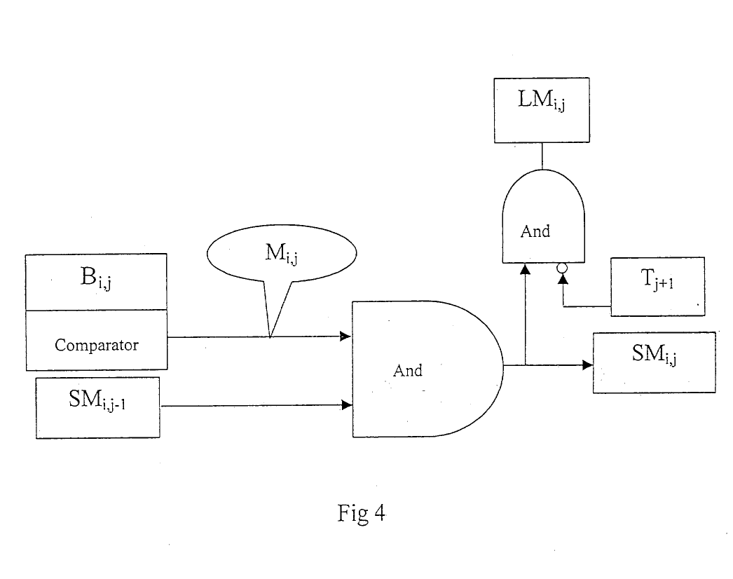

FIGS. 3 and 4 show a preferred embodiment for the implementation of this new condition. An array of words of memory is shown, each word Wᵢ being composed of a number w of sub-words B_{i,j}, {B_{i,1} to B_{i,w}}. In FIG. 3, three Words only are shown, W₁, W₂ and W_{w} and for each word respectively the three Sub-Words are shown at positions 1,2 and w.

The designation B_{i,j} is used to describe a Sub-Word of Word Wᵢ at position J, and the circuit associated with each of Sub-Words B_{i,j} respectively is shown in FIG. 4. Each Sub-Word B_{i,j} is an element of the memory, being able to store digital data of a given size. Each Sub-Word B_{i,j} also comprises a comparator, as shown in FIG. 4 and as described above in reference to FIG. 2. The said comparator outputs a matching signal if the sub-word data and the data set on the bit lines verify a given relationship. The details of the memory components are not shown here, the storage and retrieving means being of the known type. As explained above, the memory components provide means to address each memory cell for reading or writing. Each sub-word further comprises a comparator to compare data stored in the sub-word with the data presented to the memory by means of the bit lines. A priority encoder circuit, not shown here, may be used to select one unique cell, and output its address, in the case where several Word-Match signals are activated. Such priority encoder circuits or priority mask circuits have been described in PCT/IL 00/00121.

Referring to FIG. 4, the Sub-Word match signal M_{i,j} of a given Sub-Word B_{i,j} is set according to the output of the comparator of that Sub-Word.

In order to detect consecutive Matching Sub-Words of a Word Wᵢ, starting from a first Sub-Word B_{i,1} a “Still Match” signal SM_{i,j} is assigned to each Sub-Word.

Each “Match” output M_{i,j} of a Sub-Word B_{i,j} is combined with the “Still-Match” signal SM_{i,j-1} of the previous Sub-Word of the same Word by means of an AND logic gate. The first Sub-Word B_{i,1} of a Word Wᵢ is an exception, in which case SM_{i,1} is just set to the same signal as M_{i,j}.

The Still Match signal SM_{i,j} is set (logic 1) if all Sub-Words B_{i,k} with k≦j contain matching data. For each word having at least a first Sub-word matching, we now have a chain of set Still Match signals SMij. We shall further refer to that chain as the Matching Chain and the task to find the Longest Match will be performed by finding the longest Matching Chain.

It will be understood that the logic arrangement to form the Matching Chain as shown in FIGS. 3 and 4 is an example of the preferred embodiment, and other combinations of logic gates may be used to achieve the same results. For example, one could use a wide AND gate, gathering all previous M_{i,k} with k≦j in order to verify that all Sub-Words B_{i,k} have matching data. Such combinations or addition of logic gates may be employed for example in order to shorten the response time of the system. In these combinations the same logic function of the M_{i,k}, would be obtained, i.e. that the SM_{i,j} signal is set only in case that the whole chain of Sub-words B_{i,k} with k≦j have matching data.

Referring now to FIG. 3, the task of finding the length of the longest Matching Chain(s) is performed in the following way:

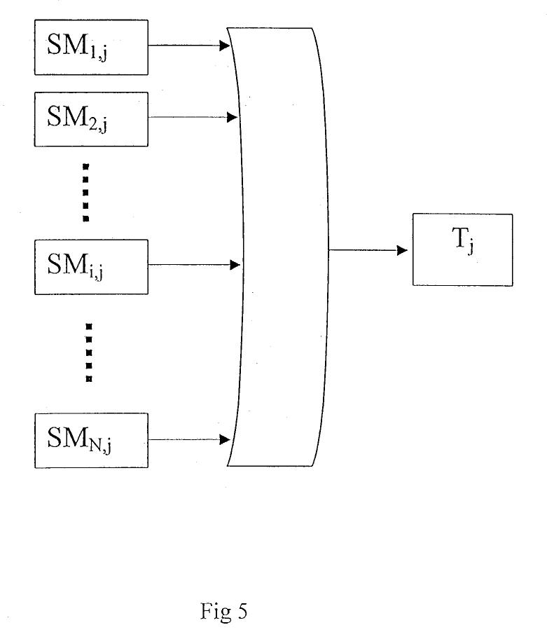

For each possible position j of a Sub-word, with the exception of the first position, a Transversal line Tⱼ is associated. Thus in total a number w−1 of Transversal lines are defined, T₂ to T_{w}. Each line Tⱼ is then set to logic level 1 if and only if at least one Sub Word at a position j among all Sub Words at that position generates a Still-Match Signal SM_{i,j}. This is done by means of an “OR” combination of all SM_{i,j} signals of all words Wᵢ for a given sub-word position j. This Or connection, shown in FIG. 3, is further enlarged and clarified in FIG. 5.

In this way, each Word “Marks” on the transversal lines its ultimate length of matching chain. Finally the Tj line at logical level 1 with the highest j indicates the length of the longest Matching Chain.

The task of detecting the Sub-Word(s) at the end of the longest match chain is shown in FIG. 4: at each Sub-Word B_{i,j} the signal on associated transversal line Tⱼ and the signal on the next transversal line Tⱼ₊₁ are combined in a logic gate to form a “Longest Match” signal LMi,j if the following condition is verified:

Signal on line Tⱼ is set, but signal on line Tⱼ₊₁ is not set.

This condition is implemented by combining in an AND gate the Still-Match signal SM_{i,j} and the inverted state of the Tⱼ₊₁ transversal line, as shown in FIG. 4. A special case is defined for the last Sub-Word B_{i,w} of a word Wᵢ. In that case, if the Still Match signal SM_{i,w} is set, it is obviously in the longest Matching Chain, since w is the maximum number of Sub-Words in a Word. Therefore for the said last Sub-Word B_{i,w} the signal LM_{i,j} is set identical to signal SM_{i,j}.

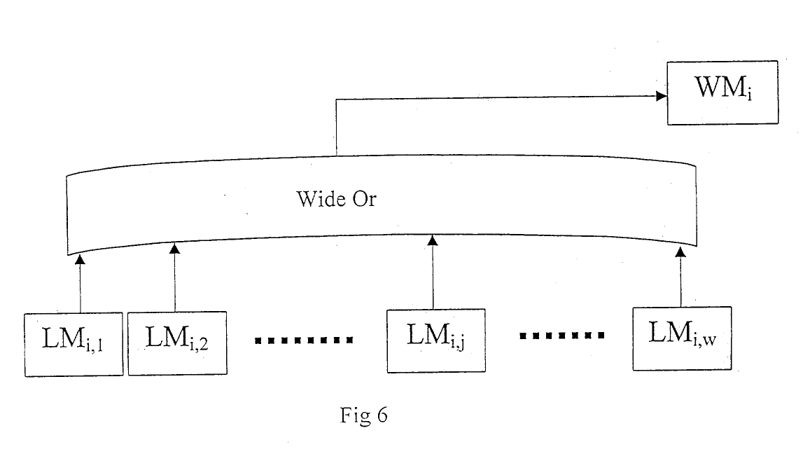

Now remains the task of activating the Word Match signal for each word where a Matching Chain with the longest length has been detected, shown in FIG. 6. As seen in FIG. 6, all the LM_{i,j} of a Word Wᵢ are collected into a “Wide OR” logic gate so as to set the Word Match signal WM_{i,j}.

As described above with reference to the drawings, the inventive circuit and system is used to activate the Word-match signal WMᵢ of a word Wᵢ according to the Longest-Match condition. As in the case of standard CAM, several words of memory may activate the Word Match signal, each one satisfying the Longest-Match condition. However a CAM or COM may include a priority encoder, or a Priority Mask, in order to select only the Address of one cell for output, the selection being done according to the priority system of the specific type of CAM or COM.

It will be understood that the invention has been described hereinabove by way of example and in respect of a preferred embodiment, and many other designs may be implemented that still remain within the scope of the invention and the claims. Thus for example other components may be employed for connecting the various elements instead of the lines of the preferred embodiment.

Example of a VLSI Implementation:

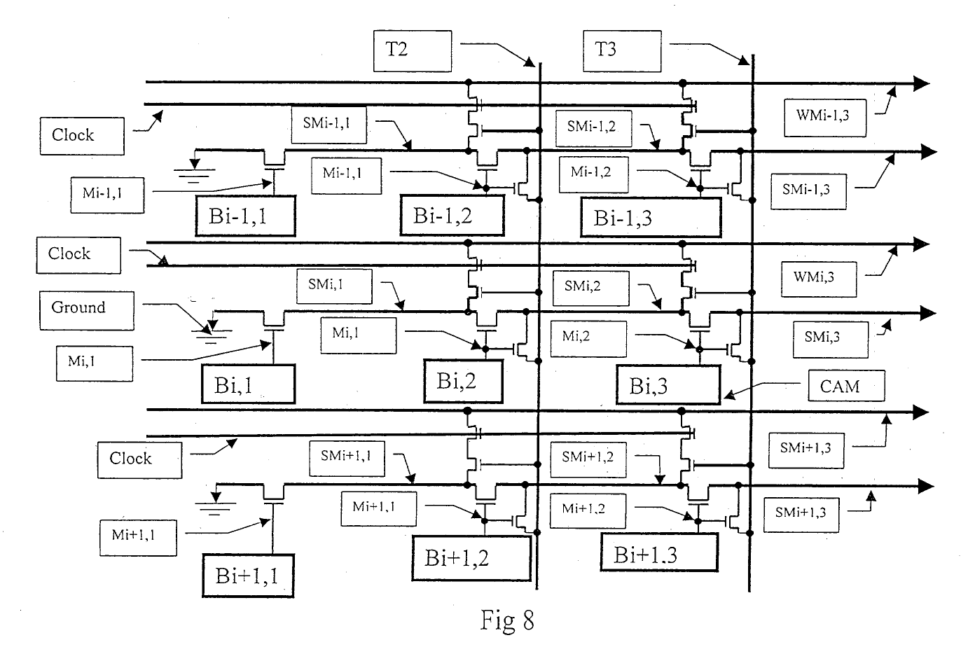

FIG. 8 shows the embodiment for the first, second and third Sub-Words, respectively designated Bi−1,1; Bi 1 and Bi+1,1 for which, as mentioned above, no transverse lines are implemented.

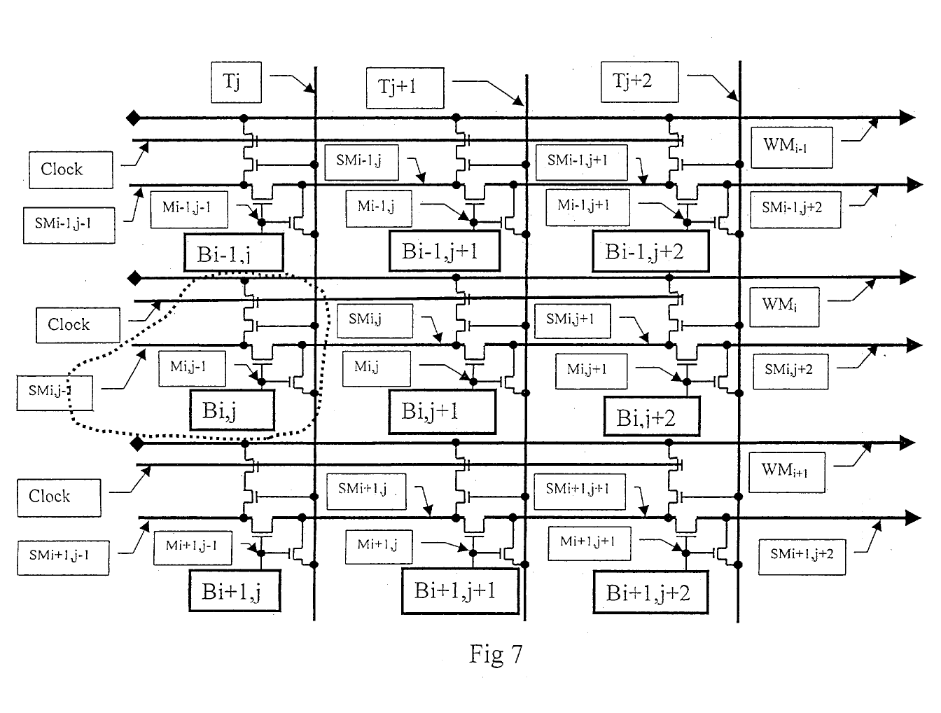

In FIGS. 7 and 8, a preferred embodiment is shown for a VLSI implementation, in which the OR functions are implemented using transistors to discharge lines, and where the Matching Chains are implemented by transistors in series. FIG. 8 shows the generic arrangement for Words Wi−1, Wi, and Wi+1 with three Sub-Words numbers j, j+1 and j+2 for each of the said words Wi−1, Wi, and Wi+1 respectively.

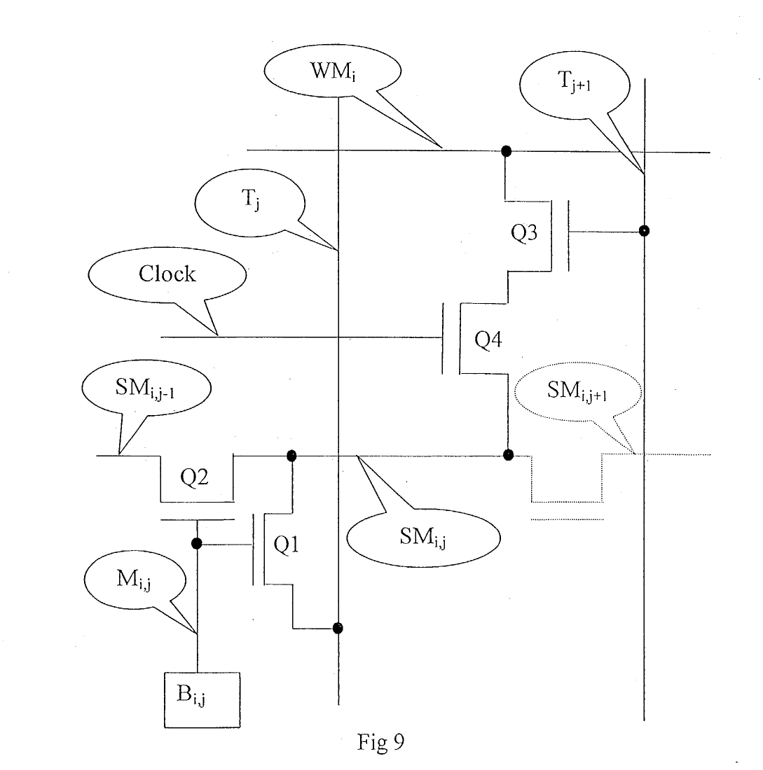

In FIG. 9 the circuit associated to one Sub-word Bi,j is shown. As seen in FIG. 9, to each Sub-Word B_{i,j}, four transistors Q1 to Q4 are associated. The still match signals SM_{i,j} are set on portions of lines associated to each sub-word respectively as shown in FIG. 9 for the still match signals Smij−1 and Smij. These portions of lines will be referred to as SM_{i,j} lines. All SM_{i,j} lines of one word are connected in serie, one end of each SM_{i,j} line being connected to the previous SM_{i,j-1} line, and the other end to the next SMi,j+1 of the same word, by a transistor Q2. The gate of the transistor Q2 of a Sub-Word B_{i,j}, connecting SM_{i,j} line with SM_{j,i-1}, is connected to the Sub-Word match signal of that Sub-Word B_{i,j}, so that if the Sub-Word has matching data, then the transistor is conducting, and line SM_{i,j} is connected to line SM_{i,j-1}. FIG. 8 further shows the special case for a first Sub-Word B_{i,1} of a Word Wᵢ. The SM_{i,1} line of the said first Sub-Word B_{i,1} is connected to ground (zero volt) by a transistor, the gate of which is connected to the Sub-Word match signal of B_{i,1}.

In an initialization phase, all SM_{i,j} lines, all Transversal lines Tⱼ and all Word Match lines are precharged, precharging being a common technique in VLSI. Also, a clock signal is first set to a zero voltage. It will be understood that when using reverse logic, the Word Match Lines will be predischarged instead of being precharged as known.

Upon activating the memory for the Longest Match detection, the Sub-Word match signals will be set for all Sub-words having a matching signal. Considering now a particular Sub-Word B_{i,j} shown in FIG. 9, the Sub-Word matching signal will cause the transistor Q2 to conduct, and will equalize the potential of the SMi,j line to that of the previous Sub-Word SM_{i,j-1} line. Referring now to FIG. 8, if all previous Sub-Words B_{i,k} with k<j are matching, then at the first Sub-Word, the still match signal SM_{i,1} will be connected to ground, and all SM_{i,k} lines will be discharged through transistors Q2 to ground. In that way, a line section SM_{i,j} will be discharged to ground only if all Sub-Words B_{i,1} to B_{i,j} contain matching data. If we define zero potential the logic level 1 for these SM_{i,j} lines, this implements a function equivalent to the Matching Chain described above.

Referring again to FIGS. 7 and 8 and according to the principle of the invention described above, Tj transverse lines are assigned to each Sub-Word position respectively, and if the Matching-Chain of a Word Wᵢ reaches the Sub-Word B_{i,j} then the Tⱼ line assigned to the said B_{i,j} Sub-Word B_{i,j} is set to logical 1. This is done in the following way, as shown for a Sub Word Bi,j in FIG. 9:

Each transversal line Tⱼ is connected at each Sub-Word B_{i,j} to the SM_{i,j} line through a transistor Q1, the gate of that transistor being connected to the Sub-Word match signal M_{i,j} of the said Sub Word B_{i,j}.

In the case where the SM_{i,j} is discharged (logical level 1), the transversal line Tⱼ will also discharge trough transistor Q1 made conducting by the Match Signal M_{i,j}, and through the chain of all SMi,k lines with k≦j, implementing the equivalent of the OR function shown in FIG. 5.

As seen in FIG. 9, that is an enlarged drawing of the area in FIG. 8 that is encircled by a dashed line, The Q4 and Q3 transistors connect the Word Match line to the SMi,j lines.

After all matching signals have been set, the clock signal is now set to a high potential and applied to all Q4 transistors, making them conducting. The gate of Q3 transistor of a Sub-Word Bi,j is connected to the next transversal line Tj+1. If this transversal line Tⱼ₊₁ has not been discharged (i.e. it remains at logical level 0), meaning that no Matching Chain has reached the j+1 Sub-Word, then transistor Q3 is left conducting, having its gate connected to the line Tⱼ₊₁. If now the still match signal SM_{i,j} is discharged to ground, meaning that the Matching Chain have reached the Bi,j Sub-Word, then the Word Match line will also be discharged to ground through transistors Q3 and Q4.

In other words, the Word Match line will be discharged if the following conditions are fulfilled:

At one Sub-Word position Bi,j—

SMi,j is discharged, implying that all Sub-Words Bi,k with k≦j have matching data

Transversal line Tj+1 has not been discharged, implying that none of the other words has consecutive matching data up to SubWord j+1;

This ensures that the Word Match line will be discharged only for Words having the longest chain of matching Sub-Words.

The system and circuit shown above thus provide means to selectively set a signal for each word of memory, in the case where that word of memory contains the longest chain of consecutive matching Sub-Words among all words of the memory, the said chain starting at a given word position.

It must be understood that the same logical function can be implemented in several different ways, with or without a clock signal and different combinations of gates and/or discharge circuits may be used to make the invention. However the method and principle of this invention provide a general description that includes the different ways and modes of circuit design that enable implementation.

It will be understood that the drawings are schematic representations of electronic circuits using straight geometric lines and the actual configuration of the inventive circuits may not conform to the drawings.

1. A circuit to be iplemented in content addressable memories for finding a word with the longest match to the searched data wherein each memory cell is able to store a word of data, the said word being composed of a group of sub words in a predefined sequence, each sub word comprises a storage circuit and a comparator circuit, each sub word is composed of one or more bits of memory and each subword is connected to a still match line together with all the subwords that are preceding to the said subword in the said predefined order by a first circuit that performs a logical AND function over all the matching signals of the said subwords and all the still match signals resulting from the said logical function from all subwords having the same position within the said predefined sub word sequence of their respective words are connected to the said transversal lines via a first wide OR circuit, at each subword position a second AND circuit connects the said still match signal and the inverse signal of the transversal line that is associated with the next subword and all the outputs of the said second AND circuits for all the subwords of one word are connected to a second wide OR circuit whereby a given word of memory Will output a word match signal wherever it has the largest number of consecutive matching sub words.

2. A circuit as claimed in claim 1 wherein the said first AND circuit is implemented by a series of AND gates, one AND gate associated with each subword respectively, the said AND gate receiving as input the match signal of the said subword and the still match signal of the preceding subword.

3. The circuit of claim 1 implemented in a VLSI device wherein one or more of the said AND circuits comprises transistors in series for charging or discharging predischarged or precharged lines respectively.

4. The circuit of claim 1 implemented in a VLSI device wherein one or more of the said OR circuits comprises transistors in parallel for charging or disharging predischarged or precharged lines respectively.

5. A circuit according to any of claims 1, 3 or 4 wherein a clock signal is used to synchronize the operation cycles.

6. A method to be applied in content addressable memories for finding a word with the longest match to the searched data wherein a word of data is stored in each memory cell, the said word of data is composed of a group of sub words in a predefined order, each sub word is composed of one or more bits of memory and all sub words having the same position within the sub word sequence of their respective words are associated with one tranversal line, comprising the following steps:
a) setting a still match signal for a first subword that matches the searched data
b) setting a still match signal for a subword in the event that all the previous match signals, for all subwords of the same word in a pre-defined order have been set, the said still match signal being the AND logic combination of the associated sub-word matching signal and all the preceding, in the said predefined order, still match signals
c) setting the transversal line to logical 1 if a still match is set for any of the subwords to which the said transversal line is associated
d) setting a longest match signal at the last consecutive matching subword of a word if the conditions are satisfied that: i)—the still match signal of that sub-word is set, and ii)—the transversal line at the next sub-word position in the word is not set.
e) Setting a word match signal if any of the longest match signals for any subword of the said word is set.

7. A method as claimed in claim 6 hereinabove wherein the said content addressable memory registers the size of the Longest Match according to the number of transversal lines that have been set and an exact search can be done using a second content addressable memory of the common type, while masking the bits beyond the longest match.

8. A method as claimed in claim 6 hereinabove wherein the said content addressable memory registers the size of the Longest Match according to the number of transversal lines that have been set and an exact search can be done using the same CAM or COM working in a common CAM or COM mode.

9. A still match signal in a memory with a plurality of data words, each data word comprising a group of sub words in a predefined order and the said still match signal being separately set for each of said sub words respectively wherein the said still match signal is set if all previous still-match signals, according to the said pre-defined order, of all previous sub words of the same data word are set, each still-match signal being the output of an AND function of the associated sub-word matching signal and the previous, in a predefined order, still match signal.

10. A set of transversal lines in a content addressable memory with a plurality of words of data, each word of data comprising a group of subwords, the said subwords occupying a sequence of possible positions in a predefined order, and one of the said transversal lines being associated to each of the said possible subword positions within each of the said words respectively wherein a transversal line is set if all the subwords within one of the said words of data that are preceding to the position of the subword that is associated with the said transverse line and the said subword itself are matching the searched information.

11. A longest match signal in a memory with a plurality of data words, each data word comprising a group of sub words in a predefined order, the said longest match signal being separately associated to each of the said sub words respectively wherein the said longest match signal is set for a data word if a) the said still match signal is set for a sub word of the said word and b) the said transversal line at the next sub word position in the said word is not set.

12. A set of word match lines in a memory with a plurality of data words, each data word comprising a group of sub words in a predefined order, one word match signal being separately associated to each of the said sub words respectively wherein the said longest match signal is set for a data word if a) the said still match signal is set for a sub word of the said word and b) the said transversal line at the next sub word position in the said word is not set.
